(19) United States
(12) Patent Application Publication
(10) Pub. No.: US 2013/0312821 A1
(43) Pub. Date: Nov. 28, 2013

(54) SOLAR CELL

(71) Applicant: AU OPTRONICS CORPORATION, HSIN-CHU (TW)

(72) Inventors: John LIU, HSIN-CHU (TW); Chi-Lin CHEN, HSIN-CHU (TW); I-Min CHAN, HSIN-CHU (TW)

(73) Assignee: AU OPTRONICS CORPORATION, HSIN-CHU (TW)

(21) Appl. No.: 13/713,066

(22) Filed: Dec. 13, 2012

(30) Foreign Application Priority Data
May 25, 2012 (CN) 201210165699.8

(51) Int. Cl. H01L 31/02

(52) U.S. Cl. CPC H01L 31/02008
USPC 136/256

(57) ABSTRACT

A solar cell is provided and includes a main body, a plurality of first finger electrodes, a first ribbon, and a second ribbon. The main body includes a first surface and a second surface opposite to the first surface. The first finger electrodes are located on the first surface, and each of the first finger electrodes includes an end portion bendably extending to the second surface. The first ribbon is located on the first surface and is electrically connected to the first finger electrodes. The second ribbon is located on the second surface and is electrically connected to the first finger electrodes.

### RELATED APPLICATIONS

This application claims priority to China Application Serial Number 201210165699.8, filed May 25, 2012, which is herein incorporated by reference.

### BACKGROUND

1. Technical Field

The present disclosure relates to a solar cell.

2. Description of Related Art

Solar cells can convert light energy (typically sunlight) into electrical energy. Since solar cells do not produce greenhouse gases during the conversion process, the energy generated by solar cells may be considered a form of green energy. Recently, along with the progress and development in photovoltaic technology, the cost of solar cells has significantly reduced, rendering solar cells more popular in the consumer market. For example, solar cells are now often seen on residence rooftops and on the external walls of buildings, as well as in various electronic products.

FIG. 1 is a top view of a conventional solar cell 300. As shown in FIG. 1, the solar cell 300 has a light-facing surface 310. A plurality of finger electrodes 320 and a ribbon 330 are formed on the light-facing surface 310. The ribbon 330 is located on and electrically connected to the finger electrodes 320. When a light (e.g., sunlight) shines on the solar cell 300, an electric current generated by the solar cell 300 can be conducted to the ribbon 330 through the finger electrodes 320. Next, the electric current can be supplied through the ribbon 330 to an electrical device (not shown) or a power storage device (not shown) which is connected to the ribbon 330.

In general, when the size of the solar cell 300 is 6″, for example, designers would typically mount at least two ribbons 330 on the light-facing surface 310 in order to get a balance between output power and material cost. However, since each of the two ribbons 330 has a width W, the light-facing surface 310 is shaded by an area equal to 2 W by the two ribbons 330. As a result, a portion of the light-facing surface 310 located under the two ribbons 330 cannot receive light, such that the photoelectric conversion efficiency of the solar cell 300 is reduced. Although it would be possible to decrease the number of the ribbons 330 so as to improve the photoelectric conversion efficiency of the solar cell 300, doing so would increase the traveling distances of the charge carriers along the fingers 320 of the solar cell 300 and the current density along the ribbons 330, such that efficiency is reduced due to the increased resistance losses. Therefore, improving the photoelectric conversion efficiency of the solar cell 300 is a difficult challenge.

### SUMMARY

An aspect of the present invention is to provide a solar cell.

In an embodiment of the present invention, a solar cell includes a main body, a plurality of first finger electrodes, a first ribbon, and a second ribbon. The main body includes a first surface and a second surface opposite to the first surface. The first finger electrodes are located on the first surface, and each of the first finger electrodes includes an end portion bendably extending to the second surface. The first ribbon is located on the first surface and is electrically connected to the first finger electrodes. The second ribbon is located on the second surface and is electrically connected to the first finger electrodes.

In an embodiment of the present invention, the first ribbon and the second ribbon are perpendicular to the first finger electrodes.

In an embodiment of the present invention, the solar cell further includes a first busbar located between the first ribbon and the first surface, and electrically connected to the first finger electrodes.

In an embodiment of the present invention, the solar cell further includes a second busbar located between the second ribbon and the second surface, and electrically connected to the first finger electrodes.

In an embodiment of the present invention, the solar cell further includes a first conductive film located between the first ribbon and the first surface, and electrically connected to the first finger electrodes.

In an embodiment of the present invention, the solar cell further includes a second conductive film located between the second ribbon and the second surface, and electrically connected to the first finger electrodes.

In an embodiment of the present invention, the solar cell further includes a plurality of second finger electrodes and a third ribbon. The second finger electrodes are located on the second surface. The third ribbon is located on the second surface and is electrically connected to the second finger electrodes.

In an embodiment of the present invention, an insulating slot is formed on the second surface and is located between the first and second finger electrodes to insulate the first and second finger electrodes.

In an embodiment of the present invention, the solar cell further includes a plurality of insulators located between the second surface and the first finger electrodes to insulate the first and second finger electrodes.

An aspect of the present invention is to provide a solar cell.

In an embodiment of the present invention, a solar cell includes a main body, a plurality of first finger electrodes, and a plurality of first ribbons. The first finger electrodes are surroundingly mounted on the main body. The first ribbons are located on the main body and are electrically connected to the first finger electrodes. A plurality of distances, each formed between two adjacent first ribbons and along the direction that the first finger electrodes extend, are the same.

In an embodiment of the present invention, the first ribbons are perpendicular to the first finger electrodes.

In an embodiment of the present invention, the solar cell further includes a plurality of first busbars located between the first ribbons and the main body, and electrically connected to the first finger electrodes.

In an embodiment of the present invention, the solar cell further includes a plurality of first conductive films located between the first ribbons and the main body, and electrically connected to the first finger electrodes.

In an embodiment of the present invention, the solar cell further includes a plurality of second finger electrodes and a second ribbon. The second finger electrodes are located on the main body and are separated from the first finger electrodes. The second ribbon is located on the main body and is electrically connected to the second finger electrodes.

In an embodiment of the present invention, the solar cell further includes a second busbar located between the second ribbon and the main body, and electrically connected to the second finger electrodes.

In an embodiment of the present invention, the solar cell further includes a second conductive film located between the second ribbon and the main body, and electrically connected to the second finger electrodes.

In an embodiment of the present invention, an insulating slot is formed on the main body and is located between the first and second finger electrodes to insulate the first and second finger electrodes.

In an embodiment of the present invention, the solar cell further includes a plurality of insulators located between the main body and the first finger electrodes to insulate the first and second finger electrodes.

In an embodiment of the present invention, the main body includes a first surface and a second surface opposite to the first surface. A number of the first ribbons is located on the first surface, and a number of the first ribbons is located on the second surface.

In the aforementioned embodiments of the present invention, the first surface may be a light-facing surface of the solar cell, and the second surface may be a back surface of the solar cell. The solar cell does not increase the moving distances of the charge carriers on the first finger electrodes (i.e., does not increase the resistance), and can increase the area of the first surface of the solar cell that is exposed to light, such that the photoelectric conversion efficiency of the solar cell can be improved. Moreover, since the ribbons can be selectively located on the first or second surfaces, the number of the ribbons and the width of each of the ribbons can be adjusted in a more flexible manner in accordance with the output power and the material cost of the solar cell.

### BRIEF DESCRIPTION OF THE DRAWINGS

FIG. 1 is a top view of a conventional solar cell;

FIG. 2 is a top view of a solar cell according to an embodiment of the present invention;

FIG. 3 is a bottom view of the solar cell shown in FIG. 2;

FIG. 4 is a cross-sectional view of the solar cell taken along line 4-4′ shown in FIG. 2;

FIG. 5 is a cross-sectional view of a solar cell according to an embodiment of the present invention;

FIG. 6 is a cross-sectional view of a solar cell according to an embodiment of the present invention;

FIG. 7 is a cross-sectional view of a solar cell according to an embodiment of the present invention;

FIG. 8 is a cross-sectional view of a solar cell according to an embodiment of the present invention;

FIG. 9 is a top view of a solar cell according to an embodiment of the present invention;

FIG. 10 is a bottom view of the solar cell shown in FIG. 9;

FIG. 11 is a cross-sectional view of the solar cell taken along line 11-11′ shown in FIG. 9;

FIG. 12 is a cross-sectional view of a solar cell according to an embodiment of the present invention;

FIG. 13 is a cross-sectional view of a solar cell according to an embodiment of the present invention;

FIG. 14 is a cross-sectional view of a solar cell according to an embodiment of the present invention; and

FIG. 15 is a top view of two solar cells connected with each other according to an embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

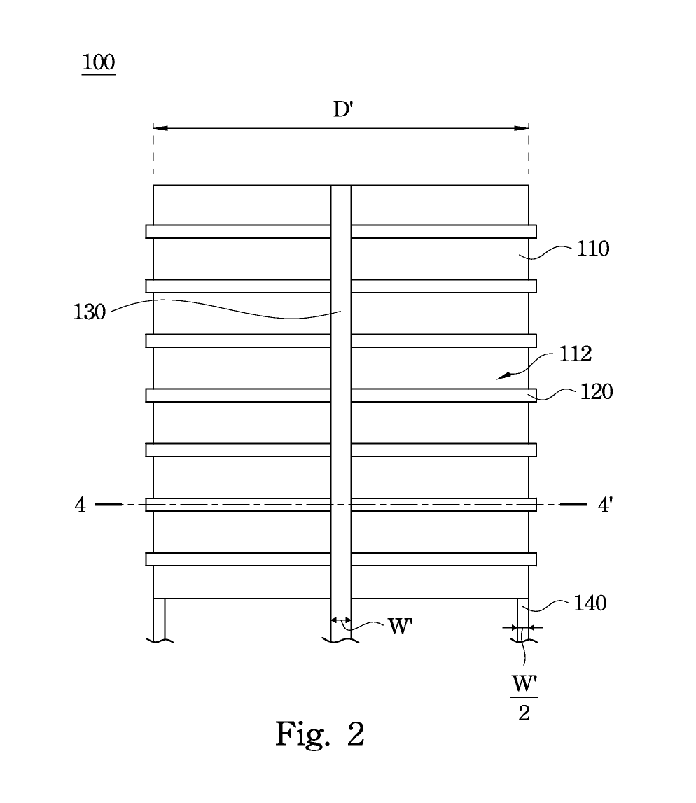

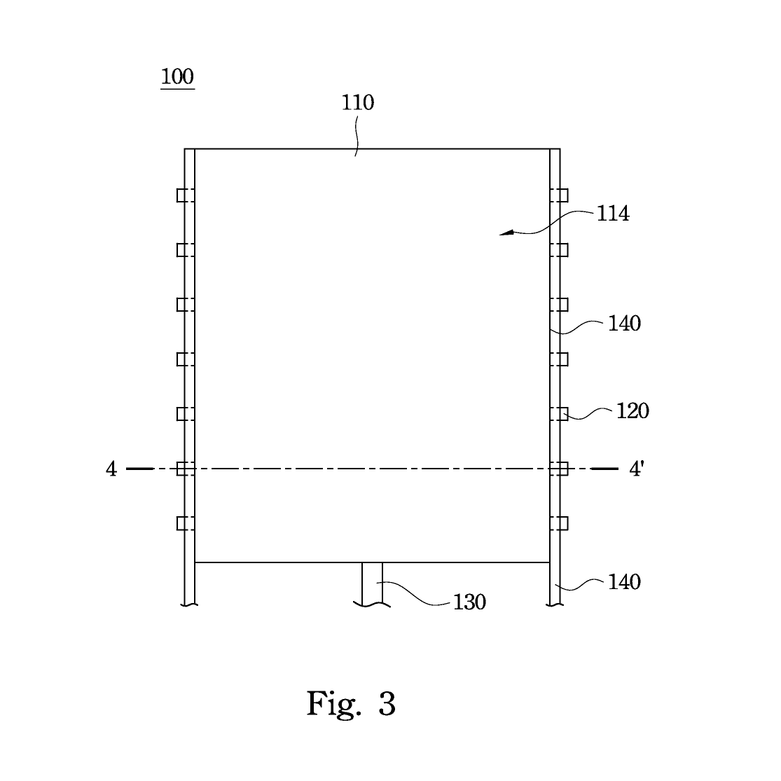

FIG. 2 is a top view of a solar cell 100 according to an embodiment of the present invention. FIG. 3 is a bottom view of the solar cell 100 shown in FIG. 2. As shown in FIG. 2 and FIG. 3, the solar cell 100 includes a main body 110, a plurality of first finger electrodes 120, a first ribbon 130, and a second ribbon 140. The main body 110 includes a first surface 112 and a second surface 114 opposite to the first surface 112. Since the first surface 112 is exposed to a light (e.g., sunlight), the first surface 112 is referred to as a light-facing surface, and the second surface 114 refers to a back surface. Moreover, the main body 110 may include a laminated photoelectric conversion layer to convert light energy into electrical energy. For example, the main body 110 may include a p-n junction, a p-i-n junction, or a heterojunction.

The structure and operation of the solar cell 100 will be described below.

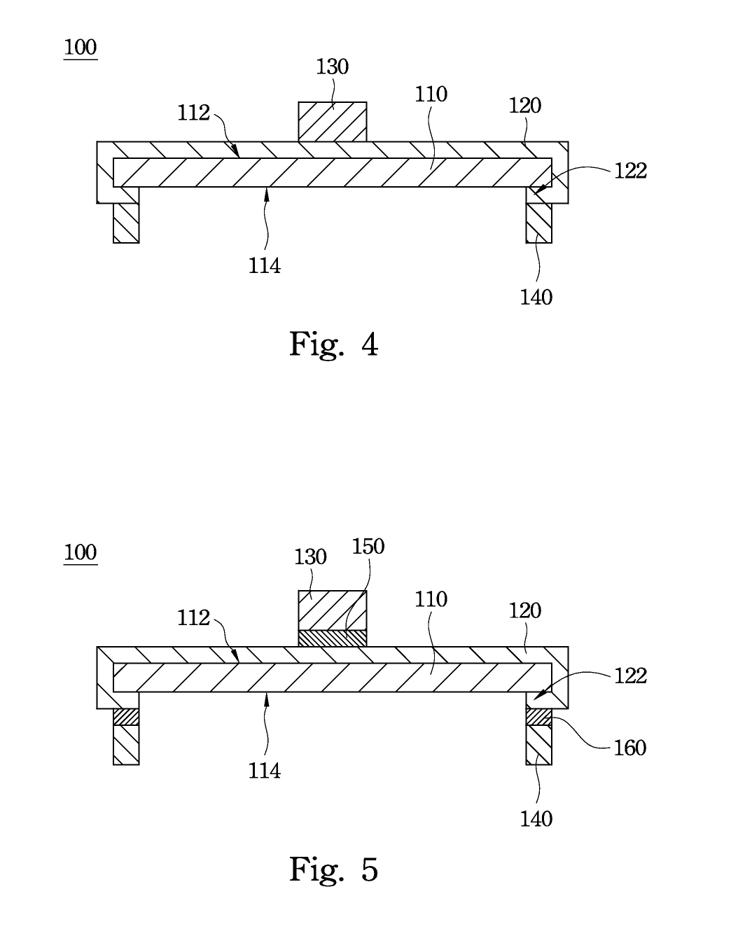

FIG. 4 is a cross-sectional view of the solar cell 100 taken along line 4-4′ shown in FIG. 2. As shown in FIG. 2 and FIG. 4, the first finger electrodes 120 are located on the first surface 112, and each of the first finger electrodes 120 includes an end portion 122 bendably extending to the second surface 114. Furthermore, the first ribbon 130 is located on the first surface 112 and is electrically connected to the first finger electrodes 120. The second ribbon 140 is located on the second surface 114 and is electrically connected to the first finger electrodes 120. The first finger electrodes 120 are substantially parallel with each other, and the first and second ribbons 130, 140 are substantially perpendicular to the first finger electrodes 120. “Substantially” is used herein to refer to the fact that there may be differences as a result of manufacturing errors.

In this embodiment, since the end portion 122 of each of the first finger electrodes 120 bendably extends to the second surface 114, the first ribbon 130 can be located on the first surface 112 and electrically connected to the first finger electrodes 120, and the second ribbon 140 can be located on the second surface 114 and electrically connected to the first finger electrodes 120. When a light shines on the first surface 112, the first surface 112 is not shaded by the second ribbon 140 located on the second surface 114, and an electric current generated by the solar cell 100 can be transmitted to the first and second ribbons 130, 140 through the first finger electrodes 120. Afterwards, the electric current is supplied to an electrical device (not shown) or a power storage device (not shown) connected to the first and second ribbons 130, 140.

Since the second ribbon 140 is located on the second surface 114, the solar cell 100 does not increase the moving distances of the charge carriers on the first finger electrodes 120, as will be described in greater detail hereinafter. Consequently, the area of the first surface 112 of the solar cell 100 exposed to light can be increased but the resistance is not increased, such that the photoelectric conversion efficiency of the solar cell 100 can be improved. Therefore, the number of the first and second ribbons 130, 140 and the width of each of the first and second ribbons 130, 140 can be adjusted in a more flexible manner by designers in accordance with the output power and the material cost of the solar cell 100.

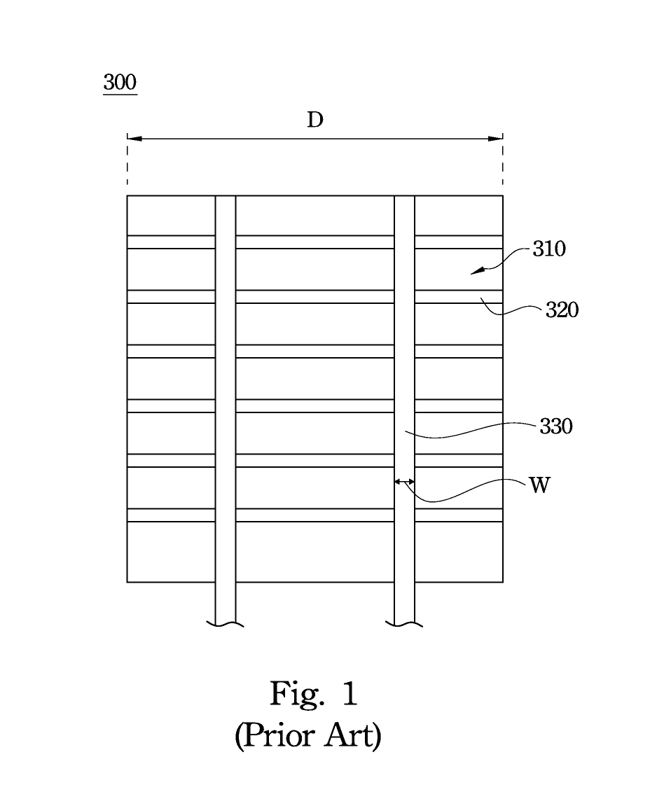

For example, compared with the conventional solar cell 300 shown in FIG. 1, the first ribbon 130 of the solar cell 100 according to this embodiment of the present invention has the width W′, each of the two second ribbons 140 has the width W′/2, and the solar cell 100 has the width D′. When the width W′ is the same as the width W of the ribbon 330 shown in FIG. 1 and the width D′ is the same as the width D of the solar cell 300 shown in FIG. 1, the moving distances of the charge carriers on the first finger electrodes 120 of the solar cell 100 are substantially the same as the moving distances of the charge carriers on the finger electrodes 320 of the solar cell 300 shown in FIG. 1. That is to say, the resistance of the solar cell 100 according to this embodiment of the present invention is substantially the same as the resistance of the conventional solar cell 300 shown in FIG. 1. However, since the second ribbon 140 is not located on the first surface 112, which is used to receive light, the area of the first surface 112 of the solar cell 100 that is exposed to light can be increased, such that the photoelectric conversion efficiency of the solar cell 100 according to this embodiment of the present invention is higher than that of the conventional solar cell 300 shown in FIG. 1.

In this embodiment, the main body 110 includes a photoelectric conversion layer. The photoelectric conversion layer may be made of a material that includes amorphous silicon, single crystal silicon, silicon heterojunction, poly silicon, cadmium diselenide (CdS), cadmium telluride (CdTe), copper indium selenide (CIS), or copper indium gallium diselenide (CIGS). The first finger electrodes 120, and the first and second ribbons 130, 140 may be made of a material that includes copper, silver, gold, nickel, aluminum, an alloy, or other conductive materials. In addition, the first finger electrodes 120 may be formed on the main body 110 by a screen-printing method. The first and second ribbons 130, 140 may be fixed on the first finger electrodes 120 by soldering or by using an adhesive tape.

In order to simplify the following description, the connection relationship of the aforementioned elements will not be repeated, and only aspects related to other structures of the solar cell 100 will be described.

FIG. 5 is a cross-sectional view of a solar cell 100 according to an embodiment of the present invention. The solar cell 100 includes the main body 110, the first finger electrodes 120 (FIG. 5 shows one of the first finger electrodes 120), the first ribbon 130, and the second ribbon 140. The difference between this embodiment and the aforementioned embodiment is that the solar cell 100 further includes a first busbar (e.g., bus electrode) 150 and a second busbar 160. The first busbar 150 is located between the first ribbon 130 and the first surface 112, and is electrically connected to the first finger electrodes 120. The second busbar 160 is located between the second ribbon 140 and the second surface 114, and is electrically connected to the first finger electrodes 120.

When light shines on the first surface 112, the first surface 112 is not shaded by the second ribbon 140 located on the second surface 114, and an electric current generated by the solar cell 100 can be transmitted to the first and second busbars 150, 160 through the first finger electrodes 120. Afterwards, the electric current is transmitted to the first and second ribbons 130, 140 by the first and second busbars 150, 160.

In this embodiment, the material of the first and second busbars 150, 160 may be the same as that of the first finger electrodes 120, namely, copper, silver, gold, nickel, aluminum, an alloy, or other conductive materials. Moreover, the first and second busbars 150, 160 may be formed on the main body 110 and the first finger electrode 120 by a screen-printing method.

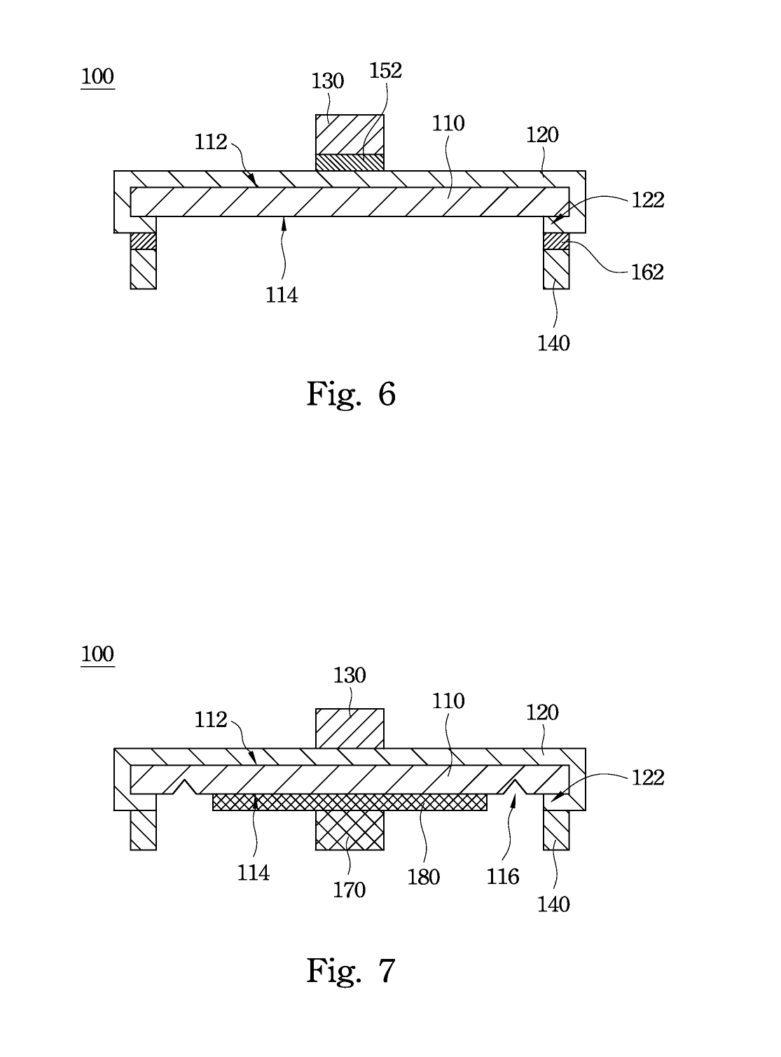

FIG. 6 is a cross-sectional view of a solar cell 100 according to an embodiment of the present invention. The solar cell 100 includes the main body 110, the first finger electrodes 120 (FIG. 6 shows one of the first finger electrodes 120), the first ribbon 130, and the second ribbon 140. The difference between this embodiment and the aforementioned embodiment shown in FIG. 5 is that the solar cell 100 further includes a first conductive film 152 and a second conductive film 162 to respectively replace the first and second busbars 150, 160 of said aforementioned embodiment. The first conductive film 152 is located between the first ribbon 130 and the first surface 112, and is electrically connected to the first finger electrodes 120. The second conductive film 162 is located between the second ribbon 140 and the second surface 114, and is electrically connected to the first finger electrodes 120.

In this embodiment, the material of each of the first and second conductive films 152, 162 may be a conductive film including micro-particles to conduct electricity.

FIG. 7 is a cross-sectional view of a solar cell 100 according to an embodiment of the present invention. The solar cell 100 includes the main body 110, the first finger electrodes 120 (FIG. 7 shows one of the first finger electrodes 120), the first ribbon 130, and the second ribbon 140. The difference between this embodiment and the aforementioned embodiment shown in FIG. 4 is that the solar cell 100 further includes a plurality of second finger electrodes 180 (FIG. 7 shows one of the second finger electrodes 180) and a third ribbon 170. The second finger electrodes 180 are located on the second surface 114. The third ribbon 170 is located on the second surface 114 and is electrically connected to the second finger electrodes 180.

In this embodiment, the solar cell 100 is a bi-facial solar cell. An insulating slot 116 is formed on the second surface 114 and is located between the first and second finger electrodes 120, 180 to electrically insulate the first and second finger electrodes 120, 180. The insulating slot 116 may be formed by a laser cutting method.

When a light shines on both the first and second surfaces 112, 114 at the same time, an electric current generated by the solar cell 100 is transmitted to the first and second ribbons 130, 140 through the first finger electrodes 120, and another electric current is transmitted to the third ribbon 170 through the second finger electrodes 180. The insulating slot 116 can prevent shorting between the first and second finger electrodes 120, 180 due to contact.

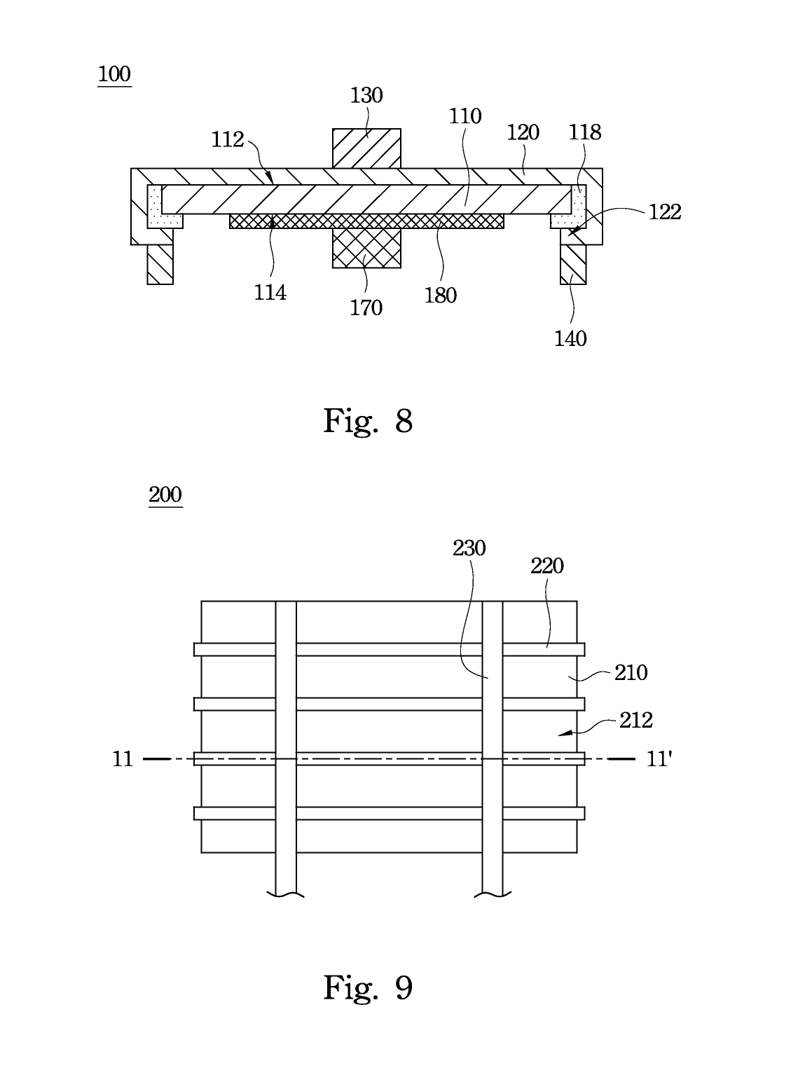

FIG. 8 is a cross-sectional view of a solar cell 100 according to an embodiment of the present invention. The solar cell 100 includes the main body 110, the first finger electrodes 120 (FIG. 8 shows one of the first finger electrodes 120), the first ribbon 130, the second ribbon 140, the second finger electrodes 180 (FIG. 8 shows one of the second finger electrodes 180), and the third ribbon 170. The difference between this embodiment and the aforementioned embodiment shown in FIG. 7 is that the solar cell 100 further includes a plurality of insulators 118 located between the second surface 114 and the first finger electrodes 120 to insulate the first and second finger electrodes 120, 180. Therefore, the insulating slot 116 (see FIG. 7) does not need to be formed on the second surface 114. In this embodiment, the insulator 118 may be made of a material that includes plastic, rubber, or another insulating material.

When a light shines on the first and second surfaces 112, 114 at the same time, the insulator 118 can prevent shorting between the first and second finger electrodes 120, 180 due to contact.

Elements and connection relationships thereamong of another solar module 200 will now be described.

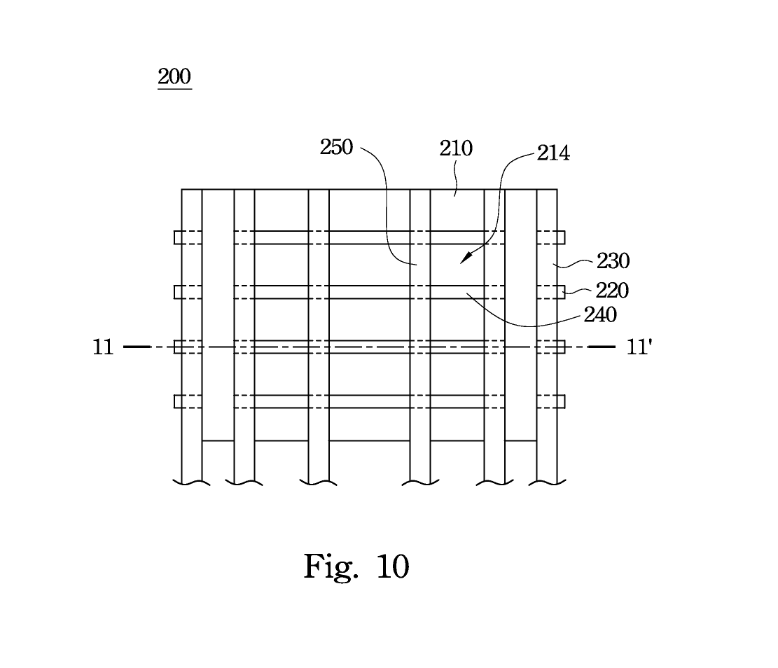

FIG. 9 is a top view of a solar cell 200 according to an embodiment of the present invention. FIG. 10 is a bottom view of the solar cell 200 shown in FIG. 9. As shown in FIG. 9 and FIG. 10, the solar cell 200 includes a main body 210, a plurality of first finger electrodes 220, a plurality of first ribbons 230, a plurality of second finger electrodes 240, and a second ribbon 250. The first finger electrodes 220 are substantially parallel with each other, and the first ribbons 230 are substantially perpendicular to the first finger electrodes 220. Similarly, the second finger electrodes 240 are substantially parallel with each other, and the second ribbons 250 are substantially perpendicular to the second finger electrodes 240. In the aforementioned description, “substantially” is used to refer to the fact that there may be differences as a result of manufacturing errors.

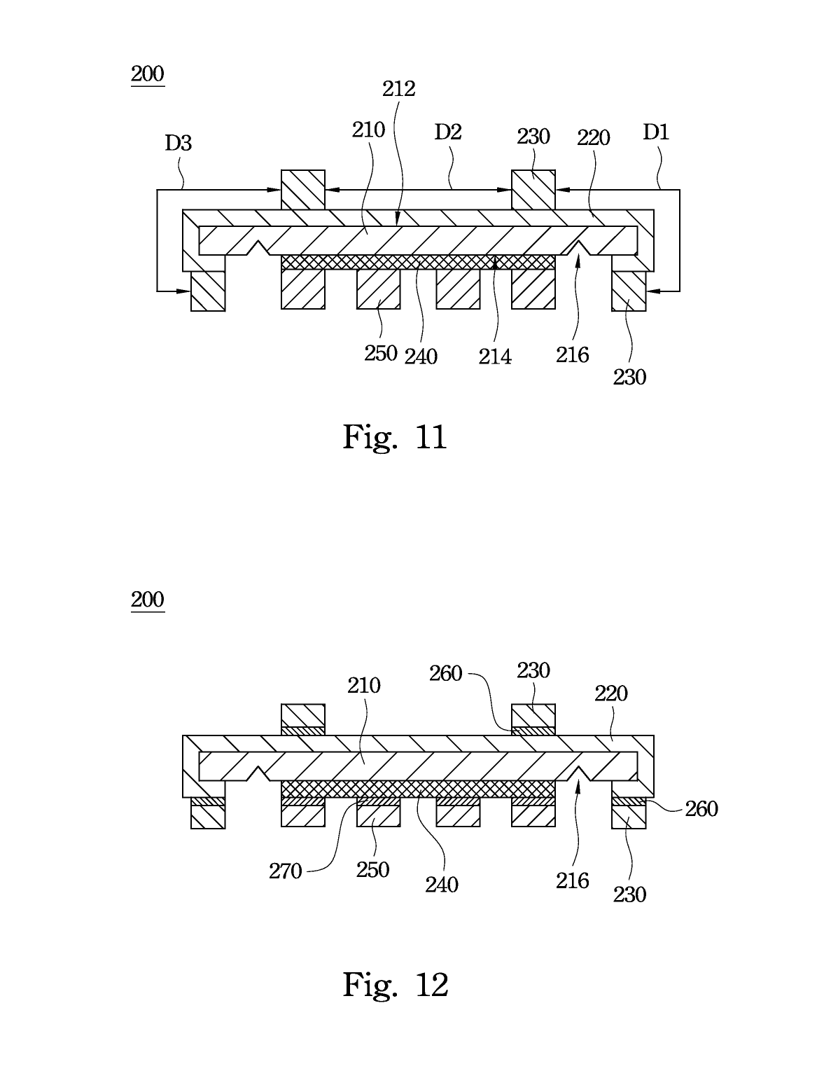

FIG. 11 is a cross-sectional view of the solar cell 200 taken along line 11-11′ shown in FIG. 9. As shown in FIG. 9 and FIG. 11, the first finger electrodes 220 are surroundingly mounted on the main body 210. The first ribbons 230 are located on the main body 210 and are electrically connected to the first finger electrodes 220. A plurality of distances, each formed between two adjacent first ribbons 230 and along the direction that the first finger electrodes 220 extend, are the same. That is to say, the distances D1, D2 and D3 are the same. As a result, the moving distances of the charge carriers on the first finger electrodes 220 are more uniform, such that efficiency loss caused by the resistance of the solar cell 200 is minimized. Moreover, the second finger electrodes 240 are located on the main body 210 and do not contact the first finger electrodes 220 (i.e., are separated from the first finger electrodes 220). The second ribbon 250 is located on the main body 210 and is electrically connected to the second finger electrodes 240.

The main body 210 includes a first surface 212 and a second surface 214 opposite to the first surface 212. A number of the first ribbons 230 is located on the first surface 212, and a number of the first ribbons 230 is located on the second surface 214.

In this embodiment, an insulating slot 216 is formed on the main body 210 and is located between the first and second finger electrodes 220, 240 to insulate the first and second finger electrodes 220, 240. Since first finger electrodes 220 are surroundingly mounted on the main body 210, a number of the first ribbons 230 can be located on the first surface 212, and a number of the first ribbons 230 can be located on the second surface 214.

Since the first surface 212 is exposed to a light, the first surface 112 is referred to as a light-facing surface. It is noted that the first surface 212 is not shaded by the first ribbons 230 located on the second surface 214, and an electric current generated by the solar cell 200 can be transmitted to the first ribbons 230 located on the first and second surfaces 212, 214 through the first finger electrodes 220. That is to say, the solar cell 200 does not increase the moving distances of the charge carriers on the first finger electrodes 220 (i.e., does not increase the resistance), and can increase the area of the first surface 212 of the solar cell 200 that is exposed to light, such that the photoelectric conversion efficiency of the solar cell 200 can be improved.

FIG. 12 is a cross-sectional view of a solar cell 200 according to an embodiment of the present invention. The difference between this embodiment and the aforementioned embodiment shown in FIG. 11 is that the solar cell 100 of this embodiment further includes a plurality of first busbars 260 and a second busbar 270. The first busbars 260 are located between the first ribbons 230 and the main body 210, and are electrically connected to the first finger electrodes 220. The second busbar 270 is located between the second ribbon 250 and the main body 210, and is electrically connected to the second finger electrodes 240 (FIG. 12 shows one of the second finger electrodes 180).

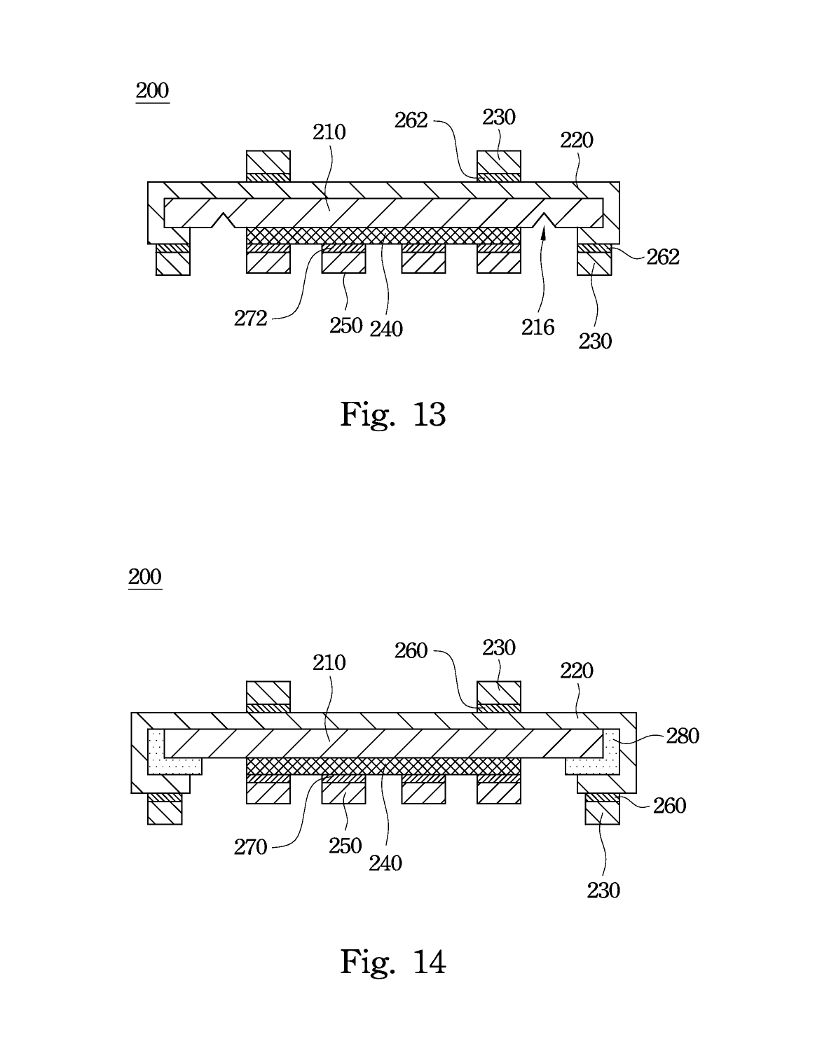

FIG. 13 is a cross-sectional view of a solar cell 200 according to an embodiment of the present invention. The difference between this embodiment and the aforementioned embodiment shown in FIG. 12 is that the solar cell 200 of this embodiment further includes a plurality of first conductive films 262 and a second conductive film 272 to respectively replace the first and second busbars 260, 270 of said aforementioned embodiment. The first conductive films 262 are located between the first ribbons 230 and the main body 210, and are electrically connected to the first finger electrodes 220. The second conductive film 272 is located between the second ribbon 250 and the main body 210, and is electrically connected to the second finger electrodes 240.

FIG. 14 is a cross-sectional view of a solar cell 200 according to an embodiment of the present invention. The difference between this embodiment and the aforementioned embodiment shown in FIG. 12 is that the solar cell 200 of this embodiment further includes a plurality of insulators 280 located between the main body 210 and the first finger electrodes 220 to insulate the first and second finger electrodes 220, 240. Therefore, the insulating slot 216 (see FIGS. 11-13) does not need to be formed on the main body 210.

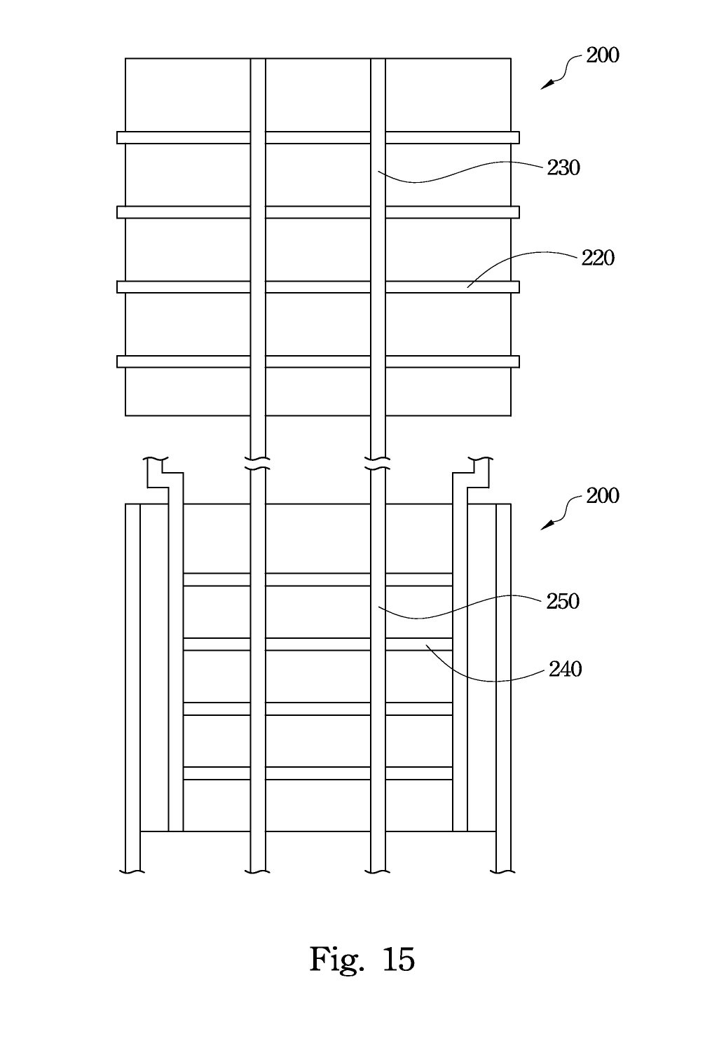

FIG. 15 is a top view of two solar cells 200 connected with each other according to an embodiment of the present invention. For convenience, the two solar cells 200 are referred to respectively as an upper solar cell 200 and a lower solar cell 200. As shown in FIG. 15, when a solar module includes a plurality of the solar cells 200, each of two adjacent solar cells 200 can be connected in series through the connection explained herein. In this embodiment, the first ribbon 230 of the upper solar cell 200 can be connected to the second ribbon 250 of the lower solar cell 200. In addition, the first ribbon 230 and the second ribbon 250 may be integrated as a single piece in accordance with practical requirements.

Compared with a conventional solar cell, the solar cell does not increase the moving distances of the charge carriers on the first finger electrodes (i.e., does not increase the resistance), and can increase the area of the first surface (e.g., a light-facing surface) of the solar cell that is exposed to light, such that the photoelectric conversion efficiency of the solar cell can be improved. Moreover, since the ribbons can be selectively located on the first surface or the second surface (e.g., a back surface), the number of the ribbons and the width of each of the ribbons can be adjusted in a more flexible manner in accordance with the output power and the material cost of the solar cell.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A solar cell comprising:
a main body including a first surface and a second surface opposite to the first surface;
a plurality of first finger electrodes located on the first surface, wherein each of the first finger electrodes includes an end portion bendably extending to the second surface;
a first ribbon located on the first surface and electrically connected to the first finger electrodes; and
a second ribbon located on the second surface and electrically connected to the first finger electrodes.

2. The solar cell as claimed in claim 1, wherein the first ribbon and the second ribbon are perpendicular to the first finger electrodes.

3. The solar cell as claimed in claim 1, further comprising:
a first busbar located between the first ribbon and the first surface, and electrically connected to the first finger electrodes.

4. The solar cell as claimed in claim 1, further comprising:
a second busbar located between the second ribbon and the second surface, and electrically connected to the first finger electrodes.

5. The solar cell as claimed in claim 1, further comprising:
a first conductive film located between the first ribbon and the first surface, and electrically connected to the first finger electrodes.

6. The solar cell as claimed in claim 1, further comprising:
a second conductive film located between the second ribbon and the second surface, and electrically connected to the first finger electrodes.

7. The solar cell as claimed in claim 1, further comprising:
a plurality of second finger electrodes located on the second surface; and
a third ribbon located on the second surface and electrically connected to the second finger electrodes.

8. The solar cell as claimed in claim 7, wherein an insulating slot is formed on the second surface and is located between the first and second finger electrodes for insulating the first and second finger electrodes.

9. The solar cell as claimed in claim 7, further comprising:
a plurality of insulators located between the second surface and the first finger electrodes for insulating the first and second finger electrodes.

10. A solar cell comprising:
a main body;
a plurality of first finger electrodes surroundingly disposed on the main body; and
a plurality of first ribbons located on the main body and electrically connected to the first finger electrodes, wherein a plurality of distances, each formed between two adjacent first ribbons and along the direction that the first finger electrodes extend, are the same.

11. The solar cell as claimed in claim 10, wherein the first ribbons are perpendicular to the first finger electrodes.

12. The solar cell as claimed in claim 10, further comprising:
a plurality of first busbars located between the first ribbons and the main body, and electrically connected to the first finger electrodes.

13. The solar cell as claimed in claim 10, further comprising:
a plurality of first conductive films located between the first ribbons and the main body, and electrically connected to the first finger electrodes.

14. The solar cell as claimed in claim 10, further comprising:
a plurality of second finger electrodes located on the main body and separated from the first finger electrodes; and
a second ribbon located on the main body and electrically connected to the second finger electrodes.

15. The solar cell as claimed in claim 14, further comprising:
a second busbar located between the second ribbon and the main body, and electrically connected to the second finger electrodes.

16. The solar cell as claimed in claim 14, further comprising:
a second conductive film located between the second ribbon and the main body, and electrically connected to the second finger electrodes.

17. The solar cell as claimed in claim 14, wherein an insulating slot is formed on the main body and is located between the first and second finger electrodes for insulating the first and second finger electrodes.

18. The solar cell as claimed in claim 14, further comprising:
a plurality of insulators located between the main body and the first finger electrodes for insulating the first and second finger electrodes.

19. The solar cell as claimed in claim 10, wherein the main body includes a first surface and a second surface opposite to the first surface, a number of the first ribbons is located on the first surface, and a number of the first ribbons is located on the second surface.
